(19) United States
(12) Patent Application Publication
(10) Pub. No.: US 2026/0040471 A1
(43) Pub. Date: Feb. 5, 2026

(54) LAYERED PRODUCT AND COMPOSITE LAYERED PRODUCT

(71) Applicant: ZEON CORPORATION, Chiyoda-ku, Tokyo (JP)

(72) Inventor: Hiroyasu INOUE, Tokyo (JP)

(73) Assignee: ZEON CORPORATION, Chiyoda-ku, Tokyo (JP)

(21) Appl. No.: 19/101,592

(22) PCT Filed: Aug. 10, 2023
(86) PCT No.: PCT/JP2023/029265

§ 371 Date: Feb. 6, 2025

(30) Foreign Application Priority Data
Aug. 22, 2022 (JP) 2022-132015

(51) Int. Cl. H05K 5/03; B32B 7/06; B32B 17/10

(52) U.S. Cl. CPC H05K 5/03; B32B 7/06; B32B 17/10; B32B 2250/03; B32B 2305/30; B32B 2307/584; B32B 2307/704; B32B 2307/7265; B32B 2307/728; B32B 2307/7376; B32B 2457/206

(57) ABSTRACT

A protective layered body including: a first substrate layer; and a first release layer disposed in contact with one surface or both surfaces of the first substrate layer, wherein the first substrate layer is a layer formed of a resin containing a polymer and having a water vapor transmission rate at 40° C. and 90% Rh of smaller than 1 g/m²/day when the first substrate layer is assumed to have a thickness of 100 μm. Also provided is a composite layered body including the protective layered body and a resin layer (R) disposed on the protective layered body to be in contact with a surface thereof on a side of the release layer, wherein, when the resin layer (R) is left to stand in an environment at 25° C. and 50% Rh for 2 hours, a weight change ratio of the resin layer (R) is 0.5% or more.

### FIELD

The present invention relates to a layered body

usefully applicable for protection of a layer capable of expressing a function such as a sealing function, and a composite layered body including the layered body.

### BACKGROUND

Optical devices such as a light-emitting device and a display device may be provided with a sealing member as a constituent element thereof. For example, an organic electroluminescent light-emitting body (hereinafter this may be appropriately referred to as “organic EL light-emitting body”) generally includes an electrode and a light-emitting layer. The light-emitting layer of the organic EL light-emitting body contains an organic material. This organic material is usually easily deteriorated by water. Therefore, in order to suppress the penetration of gas such as water vapor into the inside of the light-emitting body from outside air, the organic EL light-emitting body may be provided with a sealing member having an excellent gas barrier performance.

Use of a resin layer containing a filler that is a hygroscopic particle as such a sealing member has been known. In addition, it has been known that, in order to suppress a reduction in moisture absorption function of the resin layer in a storage period after the production of the resin layer until the installation of the resin layer in a device, the resin layer may be kept in a state wherein the surface thereof is bonded to a composite layer as a protective film, the composite layer including a gas barrier layered body and a release layer and further the gas barrier layered body including a substrate layer and an inorganic layer (see Patent Literature 1). The inorganic layer in such a protective film expresses a function of suppressing the movement of water in outside air into the resin layer. The substrate layer is a layer that supports the inorganic layer. The release layer is provided for facilitating peeling of the protective film from the resin layer when the resin layer is used. The application of such a protective film enables the resin layer to be stored for an extended period of time during which deterioration is suppressed, and the convenience in both production and use of the resin layer is significantly enhanced.

### CITATION LIST

### Patent Literature

Patent Literature 1: International Publication No. 2017/111138 (Corresponding Publication: US Patent Application Publication No. 2019/006623)

### SUMMARY

### Technical Problem

The inorganic layer in the composite layer described in Patent Literature 1 is less flexible and fragile in many cases, and therefore the inorganic layer may be easily damaged resulting in a reduction in gas barrier performance. In addition, the inorganic layer has no light transparency in many cases, and therefore whether or not defects have occurred cannot be inspected by observation of the resin layer through the composite layer that is bonded to the resin layer.

From the viewpoint of avoiding disadvantages, a layer other than the inorganic layer being used as a layer that expresses a protective function of the protective film is also conceivable. However, a layer capable of expressing a gas barrier performance, other than the inorganic layer, is a layer of a substance including a halogen element such as chlorine in many cases. When such a layer is disposed as the protective film in contact with the resin layer, the halogen element may migrate to the resin layer to cause contamination. Such contamination can cause deterioration in the device including the resin layer.

Moreover, for convenience of storage in the storage period of the resin layer, it is preferable that a composite layered body in which the protective film and the resin layer are layered can be formed into a roll of a long-length film, and it is preferable that the composite layered body can be formed into a small film roll of a thin long film. Furthermore, from the viewpoint of handling convenience when the resin layer is provided in a device, it is also preferable that the protective film is thin to a certain degree and has satisfactory flexibility.

Accordingly, an object of the present invention is to provide a protective layered body useful as a protective film that has a satisfactory gas barrier performance although the thickness of the protective film is thin and that protects a resin layer having high convenience in storage and handling and hygroscopicity, and a composite layered body that includes such a protective layered body and is satisfactorily protected.

### Solution to Problem

The present inventor has conducted studies to solve the above-described problems. As a result, the present inventor has found that the above-described problems can be solved by adopting a protective layered body including a first substrate layer formed of a specific material, and has completed the present invention. Specifically, the present invention provides as follows.
(1) A protective layered body comprising: a first substrate layer; and a first release layer disposed in contact with one surface or both surfaces of the first substrate layer, wherein
   the first substrate layer is a layer formed of a resin containing a polymer and having a water vapor transmission rate at 40° C. and 90% Rh of smaller than 1 g/m²/day when the first substrate layer is assumed to have a thickness of 100 μm.
(2) The protective layered body according to (1), wherein the polymer is an alicyclic structure-containing crystallizable polymer.
(3) A composite layered body comprising:
   the protective layered body according to (1) or (2); and
   a resin layer (R) disposed on the protective layered body to be in contact with a surface thereof on a side of the release layer, wherein
   when the resin layer (R) is left to stand in an environment at 25° C. and 50% Rh for 2 hours, a weight change ratio of the resin layer (R) is 0.5% or more.
(4) The composite layered body according to (3), wherein the resin layer (R) contains a hygroscopic filler.
(5) The composite layered body according to (3) or (4), further comprising a thin film glass that is disposed on the resin layer (R) on a side opposite to the first release layer and that has a thickness of 25 to 100 μm.
(6) The composite layered body according to (3) or (4), further comprising a counter protective layered body that is disposed on the resin layer (R) on a side opposite to the first release layer, wherein:
   the counter protective layered body is a layered body including a second substrate layer and a second release layer disposed in contact with one surface or both surfaces of the second substrate layer;
   the counter protective layered body is disposed so that a surface thereof on a side of the second release layer is disposed in contact with the resin layer (R); and
   the second substrate layer contains a polymer and has a water vapor transmission rate at 40° C. and 90% Rh of smaller than 1 g/m²/ day when the second substrate layer is assumed to have a thickness of 100 μm.

### Advantageous Effects of Invention

According to the present invention, there is provided a protective layered body useful as a protective film that has a satisfactory gas barrier performance although the thickness of the protective film is thin and that protects a resin layer having high convenience in storage and handling and hygroscopicity, and a composite layered body that includes such a protective layered body and is satisfactorily protected.

### DESCRIPTION OF EMBODIMENTS

Hereinafter, the present invention will be described in detail with reference to embodiments and examples. However, the present invention is not limited to the following embodiments and examples, and may be freely modified for implementation without departing from the scope of claims of the present invention and the scope of their equivalents.

In the following description, a “long-length” film refers to a film with a length that is 5 times or more the width, and preferably a film with a length that is 10 times or more the width, and specifically refers to a film having a length that allows a film to be wound up into a rolled shape for storage or transportation. The upper limit of the length thereof is not particularly limited, and is, for example, 100,000 times or less that of the width.

In the following description, unless otherwise specified, the expression “(meth)acryl-” is a term that includes “acryl-”, “methacryl-”, and combinations thereof. For example, “(meth)acrylic acid” is a term that includes “acrylic acid”, “methacrylic acid”, and mixtures thereof, and “(meth)acrylate” is a term that includes “acrylate”, “methacrylate”, and mixtures thereof.

In the following description, unless otherwise specified, the notation “Rh” in the humidity unit “% Rh” indicates that the humidity is relative humidity.

### Outline of Present Invention

The protective layered body of the present invention is a film that may be used as a protective film and includes a plurality of layers. Herein, the protective film is a film that suppresses moisture absorption of a layer to be protected. Herein, the moisture absorption of a layer represents that the layer absorbs a component of outside air, such as water vapor, into the inside thereof. Suppression of moisture absorption specifically refers to suppression of reduction in hygroscopic ability after the initiation of use of a layer having hygroscopic ability, the reduction being caused by absorption of water in outside air prior to its use utilizing its hygroscopic ability thereof.

The composite layered body of the present invention is a layered body including the protective layered body of the present invention and a resin layer (R) that is a specific resin layer to be protected.

### Protective Layered Body

The protective layered body of the present invention includes a first substrate layer and a first release layer disposed in contact with one surface or both surfaces of the first substrate layer. Herein, two layers “disposed in contact with each other” represent that the two layers are disposed without a layer interposed between the layers.

The term “first” in the first substrate layer and the first release layer is a term to distinguish them from a second substrate layer and a second release layer described later. When the distinguishment between the first and second substrate layers or between the first and second release layers is obvious from the context, and when the first and second substrate layers or the first and second release layers are collectively referred to, they may be simply referred to as “substrate layer” or “release layer”, respectively.

### Resin Constituting First Substrate Layer

The first substrate layer is a layer formed of a resin containing a polymer. The polymer may be a crystallizable polymer. In the following description, a resin containing a crystallizable polymer may be referred to as a “crystallizable resin”.

The crystallizable polymer is a polymer having crystallizability. Herein, the “polymer having crystallizability” refers to a polymer having a melting point Tm. The polymer having a melting point Tm specifically refers to a polymer of which a melting point Tm is observable by a differential scanning calorimeter (DSC). When the crystallizable resin includes a crystallizable polymer in a certain amount or more, the crystallizable resin itself may also express the crystallizability of the crystallizable polymer.

Examples of the crystallizable polymer may include an alicyclic structure-containing crystallizable polymer and a polystyrene-based crystallizable polymer (see Japanese Patent Application Laid-Open No. 2011-118137 A). Among these, an alicyclic structure-containing crystallizable polymer is preferable. In general, an alicyclic structure-containing polymer is excellent in transparency, low moisture permeability, size stability, and lightweight properties, and the alicyclic structure-containing crystallizable polymer has particularly low moisture permeability and is particularly excellent as a constituent element of the protective layered body of the present invention. In addition, the alicyclic structure-containing crystallizable polymer has lower repellency against a coating liquid for formation of a release layer when forming a release layer compared with an alicyclic structure-containing non-crystallizable polymer in many cases, and therefore a satisfactory release layer can be easily formed. Specifically, problems such as cracking of the release layer can be reduced.

The alicyclic structure-containing polymer refers to a polymer that has an alicyclic structure in its molecule, and is a polymer obtainable by a polymerization reaction using a cyclic olefin as a monomer or a hydrogenated product thereof. However, the polymer is not limited by the production methods.

Examples of the alicyclic structure may include a cycloalkane structure and a cycloalkene structure. Among these, a cycloalkane structure is preferable because a substrate layer having excellent properties such as excellent thermal stability is thereby easily obtained. The number of carbon atoms contained in one alicyclic structure is preferably 4 or more, and more preferably 5 or more, and is preferably 30 or less, more preferably 20 or less, and particularly preferably 15 or less. When the number of carbon atoms contained in one alicyclic structure falls within the above-described range, mechanical strength, heat resistance, and moldability of the crystallizable resin are highly balanced.

In the crystallizable polymer, the ratio of the structural unit having an alicyclic structure relative to all structural units is preferably 30% by weight or more, more preferably 50% by weight or more, and particularly preferably 70% by weight or more. By setting the ratio of the structural unit having an alicyclic structure to the above-described high ratio, heat resistance can be enhanced.

In addition, in the crystallizable polymer, the residual portion other than the structural unit having an alicyclic structure is not particularly limited, and may be appropriately selected according to the purpose of use.

Preferable examples of the crystallizable polymer may include the following polymers (α) to (δ). Among these, the polymer (β) is particularly preferable because a substrate layer having excellent heat resistance can thereby be easily obtained.
Polymer (α): a ring-opening polymer of a cyclic olefin monomer having crystallizability
Polymer (β): a hydrogenated product of the polymer (a) having crystallizability
Polymer (γ): an addition polymer of a cyclic olefin monomer having crystallizability
Polymer (δ): a hydrogenated product and the like of the polymer (γ) having crystallizability

More specifically, the crystallizable polymer is more preferably a ring-opening polymer of dicyclopentadiene having crystallizability or a hydrogenated product of the ring-opening polymer of dicyclopentadiene having crystallizability. The crystallizable polymer is particularly preferably a hydrogenated product of the ring-opening polymer of dicyclopentadiene having crystallizability. Herein, the ring-opening polymer of dicyclopentadiene refers to a polymer in which the ratio of a structural unit derived from dicyclopentadiene relative to all structural units is usually 50% by weight or more, preferably 70% by weight or more, more preferably 90% by weight or more, and further more preferably 100% by weight.

The crystallizable polymer containing an alicyclic structure preferably has a syndiotactic structure, and more preferably has a high degree of syndiotactic stereoregularity. By having such a structure, the crystallizability of the polymer can be increased, and thus the tensile modulus can be particularly increased. The degree of syndiotactic stereoregularity of the crystallizable polymer may be expressed by the ratio of the racemo diad of the crystallizable polymer. The specific ratio of the racemo diad is preferably 51% or more, more preferably 60% or more, and particularly preferably 70% or more. The ratio of the racemo diad may be measured in the manner described in Examples section.

As the crystallizable polymer, one type thereof may be solely used. Alternatively, two or more types thereof may also be used in combination at any ratio.

The crystallizable polymer does not have to be crystallized prior to production of the layered body. However, after the layered body of the present invention is produced, the crystallizable polymer contained in the layered body can usually have a high crystallization degree as a result of crystallization. The specific range of the crystallization degree may be appropriately selected according to desired performances, and is preferably 10% or more, more preferably 15% or more, and particularly preferably 30% or more. By setting the crystallization degree to be equal to or higher than the lower limit value of the above-described range, it is possible to impart, to the substrate layer, low moisture permeability, high heat resistance, and appropriate affinity with the coating liquid for forming the release layer.

The crystallization degree of the polymer may be measured by an X-ray diffraction method.

The weight-average molecular weight (Mw) of the crystallizable polymer is preferably 1,000 or more, and more preferably 2,000 or more, and is preferably 1,000,000 or less, and more preferably 500,000 or less. The crystallizable polymer having such a weight-average molecular weight is excellent in the balance between molding processability and heat resistance.

The molecular weight distribution (Mw/Mn) of the crystallizable polymer is preferably 1.0 or more, and more preferably 1.5 or more, and is preferably 4.0 or less, and more preferably 3.5 or less. Herein, Mn represents a number-average molecular weight. The crystallizable polymer having such a molecular weight distribution has excellent molding processability.

The weight-average molecular weight (Mw) and the molecular weight distribution (Mw/Mn) of the polymer may be measured as a polystyrene-equivalent value by gel permeation chromatography (GPC) using tetrahydrofuran as a developing solvent.

The melting point Tm of the crystallizable polymer is preferably 200° C. or higher, more preferably 230° C. or higher, and particularly preferably 250° C. or higher, and is preferably 290° C. or lower. By using a crystallizable polymer having such a melting point Tm, it is possible to obtain a substrate layer being excellent in the balance between moldability and heat resistance.

The glass transition temperature Tg of the crystallizable polymer is not particularly limited, and is usually 85° C. or higher and usually 170° C. or lower.

The crystallizable polymer preferably has a positive intrinsic birefringence value. The polymer having a positive intrinsic birefringence value means a polymer in which the refractive index in a stretching direction becomes larger than the refractive index in a direction orthogonal thereto. The intrinsic birefringence value may be calculated from a dielectric constant distribution. By adopting a crystallizable polymer having a positive intrinsic birefringence value, it is possible to easily obtain a substrate layer having favorable characteristics such as a high orientation regulating force, a high strength, a low cost, and a low thermal size change rate.

The method for producing the crystallizable polymer may be any optional method. For example, a crystallizable polymer containing an alicyclic structure may be produced by the method described in International Publication No. 2016/067893.

The ratio of the crystallizable polymer in the crystallizable resin is preferably 50% by weight or more, more preferably 70% by weight or more, and particularly preferably 90% by weight or more. By setting the ratio of the crystallizable polymer to the lower limit value or higher of the above-described range, the heat resistance of the substrate layer can be enhanced.

The crystallizable resin may contain an optional component in addition to the crystallizable polymer. Examples of the optional components may include an antioxidant such as a phenol-based antioxidant, a phosphorus-based antioxidant, and a sulfur-based antioxidant; a light stabilizer such as a hindered amine-based light stabilizer; a wax such as a petroleum-based wax, a Fischer-Tropsch wax, and a polyalkylene wax; a nucleating agent such as a sorbitol-based compound, a metal salt of an organic phosphoric acid, a metal salt of an organic carboxylic acid, kaolin, and talc; a fluorescent brightener such as a diaminostilbene derivative, a coumarin derivative, an azole-based derivative (for example, a benzoxazole derivative, a benzotriazole derivative, a benzimidazole derivative, and a benzothiazole derivative), a carbazole derivative, a pyridine derivative, a naphthalic acid derivative, and an imidazolone derivative; an ultraviolet absorber such as a benzophenone-based ultraviolet absorber, a salicylic acid-based ultraviolet absorber, and a benzotriazole-based ultraviolet absorber; an inorganic filler such as talc, silica, calcium carbonate, and glass fiber; a colorant; a flame retardant; a flame retardant auxiliary; an antistatic agent; a plasticizer; a near-infrared absorber; a lubricant; and an optional polymer other than the crystallizable polymer such as a filler and a soft polymer. As the optional component, one type thereof may be solely used. Alternatively, two or more types thereof may also be used in combination at any ratio.

It is preferable that the resin constituting the first substrate layer, such as a crystallizable resin, does not contain a halogen element, or has a low content ratio of a halogen element. Specifically, the ratio (weight ratio) of the halogen element relative to the entire resin is preferably 1,500 ppm or less, and more preferably 900 ppm or less. The lower limit of the ratio of halogen elements is ideally 0 ppm. When the content ratio of the halogen element falls within the range described above, the probability that the film to be protected such as the resin layer (R) is contaminated by the halogen elements can be reduced. Therefore, such a crystallizable resin is particularly useful when the film to be protected is used in the vicinity of a member that easily deteriorates by halogen elements, such as an organic EL light-emitting body.

### First Substrate Layer

The first substrate layer is a layer formed of a resin having a water vapor transmission rate at 40° C. and 90% Rh of smaller than 1 g/m²/ day when the first substrate layer is assumed to have a thickness of 100 μm.

The water vapor transmission rate of a film-shaped measurement subject, such as the first substrate layer, may be measured with a water vapor transmission rate tester (e.g., L80 series manufactured by Lyssy). Furthermore, the water vapor transmission rate of the measurement subject, when the measurement subject is assumed to have a thickness of 100 μm, may be determined by the following equation from the measured water vapor transmission rate and the thickness of the measurement subject. In the following description, the water vapor transmission rate of the measurement subject itself may be abbreviated as WVTR, and the water vapor transmission rate obtained by converting WVTR when the measurement subject is assumed to have a thickness of 100 μm may be abbreviated as WVTR (100 μm).

$$WVTR ( 100 μm ) = ( ( thickness of substrate layer ) / 100 ) \times WVTR$$

The WVTR (100 μm) of the first substrate layer is less than 1 g/m²/day, preferably 0.9 g/m²/day or less, more preferably 0.7 g/m²/day or less, and further more preferably 0.5 g/m²/day or less. The lower limit of the water vapor transmission rate is ideally 0 g/m²/day, but may be, for example, 0.05 g/m²/day or more. When the first substrate layer has such a WVTR (100 μm), the first substrate layer itself can express a satisfactory gas barrier performance even if the first substrate layer is thin, and can impart a satisfactory performance of a protective film to the protective layered body.

A first substrate layer having a low WVTR (100 μm) that is within the aforementioned range may be easily obtained by adopting the aforementioned crystallizable resin as a constituent resin. In particular, a resin containing an alicyclic structure-containing non-crystallizable polymer has a WVTR (100 μm) of 1 g/m²/day or more in many cases, while a resin containing an alicyclic structure-containing crystallizable polymer has a WVTR (100 μm) of less than 1 g/m²/day in some cases. Therefore, the resin containing an alicyclic structure-containing crystallizable polymer may be usefully applied as a material constituting the first substrate layer.

The thickness of the first substrate layer is preferably 10 μm or more, more preferably 15 μm or more, and further more preferably 25 μm or more, and is preferably 150 μm or less, more preferably 100 μm or less, and further more preferably 75 μm or less. When the thickness is within such a range, both a satisfactory gas barrier performance and high convenience in the storage and handling of the composite layered body can be simultaneously achieved. In addition, when the thickness of the first substrate layer is within such a range, a desired WVTR can be expressed in the first substrate layer.

The WVTR of the first substrate layer may be adjusted to a desired value by adjusting the thickness of the first substrate layer, and the like, so as to achieve a desired gas barrier performance. The WVTR of the first substrate layer is preferably 3.0 g/m²/day or less, more preferably 2.0 g/m²/day or less, and further more preferably 1.2 g/m²/day or less. The lower limit of the WVTR of the first substrate layer is not particularly limited. The lower limit is ideally 0 g/m²/day, and may be, for example, 0.2 g/m²/day or more.

### Method for Producing First Substrate Layer)

The aforementioned first substrate layer may be produced, for example, by a production method including a step of molding a crystallizable resin containing a crystallizable polymer into a film shape.

Molding of the crystallizable resin may be performed by a resin molding method such as an injection molding method, an extrusion molding method, a press molding method, an inflation molding method, a blow molding method, a calendar molding method, a cast molding method, and a compression molding method. Among these, an extrusion molding method is preferable because thereby the thickness can be easily controlled.

The film produced by the above-described molding method as it is may be used as the first substrate layer. Alternatively, the molded pre-stretch film may be subjected to a stretching treatment to obtain a stretched film, and the stretched film may be used as the first substrate layer. Accordingly, the method for producing the first substrate layer may include a step of stretching the film of the crystallizable resin.

The stretching method is not particularly limited, and any stretching method may be adopted. Examples of the method may include a uniaxial stretching method such as a method of uniaxially stretching a film in the lengthwise direction (longitudinal uniaxial stretching method) and a method of uniaxially stretching a film in the width direction (transversal uniaxial stretching method); a biaxial stretching method such as a simultaneous biaxial stretching method in which a film is stretched in the width direction while the film is simultaneously stretched in the lengthwise direction, and a sequential biaxial stretching method in which a film is stretched in one of the lengthwise and width directions, followed by stretching the film in the other direction; and a method in which a film is stretched in a diagonal direction that is not parallel nor vertical to the width direction (diagonal stretching method).

Examples of the longitudinal uniaxial stretching method may include a stretching method using a difference in peripheral speed between rolls. Examples of the transversal uniaxial stretching method may include a stretching method using a tenter stretching machine. Examples of the simultaneous biaxial stretching method may include a stretching method using a tenter stretching machine equipped with a plurality of clips that are installed movably along guide rails and are capable of fixing the film, and therewith the film is stretched in the lengthwise direction by increasing intervals between the clips while the film is stretched in the width direction by a spreading angle of the guide rails. Examples of the sequential biaxial stretching method may include a stretching method of stretching a film in the lengthwise direction using a difference in peripheral speed between rolls, and thereafter stretching the film in the width direction using a tenter stretching machine while gripping both ends of the film with clips. Examples of the diagonal stretching method may include a stretching method of continuously stretching a film in the diagonal direction using a tenter stretching machine capable of applying a feeding force, a pulling force, or a drawing force at different speeds on the left and right of the film in the lengthwise or width direction.

The stretching temperature is preferably Tg−30° C. or higher, and more preferably Tg−10° C. or higher, and is preferably Tg+60° C. or lower, and more preferably Tg+50° C. or lower. Herein, “Tg” refers to the glass transition temperature of the crystallizable polymer. When stretching is performed within such a temperature range, polymer molecules contained in the film can be appropriately oriented.

The stretching ratio may be appropriately selected depending on desired optical properties, thickness, strength, and the like. The ratio is usually more than 1, more preferably 1.01 or more, and more preferably 1.1 or more, and is usually 10 or less, and preferably 5 or less. The stretching ratio is a ratio of the length of the stretched article after stretching relative to the length thereof before the stretching. Herein, when stretching is performed in a plurality of different directions such as stretching by the biaxial stretching method, the stretching ratio refers to a total stretching ratio represented by the product of stretching ratios in the respective stretching directions. When the stretching ratio is equal to or less than the upper limit value of the above-described range, the possibility that the film is broken can be reduced, and thus the first substrate layer can be easily produced.

When the film formed of the crystallizable resin is subjected to the above-described stretching treatment, a first substrate layer having desired characteristics can be obtained. In addition, a thin and wide first substrate layer can be easily produced.

The first substrate layer may also be obtained by subjecting the film produced by the above-described production method to a treatment of crystallizing the crystallizable polymer contained in the film. Therefore, the method for producing the first substrate layer may include a crystallization step of crystallizing the crystallizable polymer. In the following description, a film to be subjected to the treatment for crystallizing the crystallizable polymer is appropriately called “primary film”. This primary film may be a film that has been subjected to a stretching treatment or a film that has not been subjected to a stretching treatment.

In the crystallization step, the crystallization treatment for crystallizing the crystallizable polymer is usually performed by holding at least two edge sides of the primary film formed of the crystallizable resin to be in a tensioned state, and, while keeping that state, the temperature thereof is controlled to be within a specific temperature range. By performing this step, a first substrate layer containing a crystallized crystallizable polymer can be easily produced, and therefore a first substrate layer having excellent characteristics described above can be easily obtained.

The thickness of the primary film may be optionally set according to the thickness of the first substrate layer, and is usually 5 μm or more, and preferably 10 μm or more, and is usually 1 mm or less, and preferably 500 μm or less.

The state in which the primary film is tensioned refers to a state in which tension is applied to the primary film. However, this state in which the primary film is tensioned does not include a state in which the primary film is substantially stretched. Furthermore, the state in which the primary film is substantially stretched usually refers to a state that the stretching ratio of the primary film in any direction is 1.1 or more.

When the primary film is held, appropriate holding devices are used for holding the primary film. The holding devices may be those capable of continuously holding the entire length of edge sides of the primary film or those capable of intermittently holding the primary film at intervals. For example, the edge sides of the primary film may be intermittently held by holding devices arranged at specific intervals.

In the crystallization step, at least two edge sides of the primary film are held to thereby keep the primary film to be in a tensioned state. Thus, deformation caused by heat shrinkage of the primary film is prevented at a region between the held edge sides. In order to prevent deformation at a wide area of the primary film, it is preferable that edge sides including two opposite edge sides are held and the region between the held edge sides is in a tensioned state. For example, with a primary film in a rectangular sheet piece shape, when two opposite edge sides (e.g., edge sides in long sides or short sides) are held and the region between the above-described two edge sides is in a tensioned state, deformation can be prevented over the entire surface of the primary film in a sheet piece shape. With a long-length primary film, when two edge sides at ends in the width direction (i.e., edge sides in long sides) are held and the region between the above-described two edge sides is in a tensioned state, deformation can be prevented over the entire surface of the long-length primary film. With the primary films in which deformation is thus prevented, deformation such as wrinkling is suppressed even under stress that is caused in the film by heat shrinkage. When a stretched film obtained by performing a stretching treatment is used as the primary film, deformation is more surely suppressed by holding at least two edge sides that are orthogonal to the stretching direction (in a case of biaxial stretching, a stretching direction having a larger stretching ratio).

In order to more surely suppress deformation in the crystallization step, it is preferable that a larger number of edge sides are held. For example, with the primary film in a sheet piece shape, it is preferable that all edge sides thereof are held. Specifically, it is preferable that four edge sides of the primary film in a rectangular sheet piece shape are held.

It is preferable that the holding device capable of holding the edge sides of the primary film is a holding device that does not come into contact with the primary film at a part other than the edge side of the primary film. When such a holding device is used, a first substrate layer having more excellent smoothness can be obtained.

The holding device is preferably a holding device capable of fixing a position relative to the other holding devices in the crystallization step. With such a holding device, substantial stretching of the primary film in the crystallization step can be easily suppressed since the position relative to the other holding devices does not change in the crystallization step.

An example of the suitable holding device for a rectangular primary film may be grippers that are provided on a frame at specific intervals and can grip the edge sides of the primary film, such as clips. An example of the holding device for holding two edge sides at ends in the width direction of a long-length primary film may be grippers that are provided in a tenter stretching machine and can grip the edge sides of the primary film.

When a long-length primary film is used, the edge sides at the ends in the lengthwise direction of the primary film (i.e., the edge sides on short sides) may be held. Alternatively, instead of holding the above-described edge sides, both sides in the lengthwise direction at a region to be subjected to the crystallization treatment of the primary film may be held. For example, a holding device capable of producing a state in which the primary film is held and tensioned so that heat shrinkage is not caused may be provided on both sides in the lengthwise direction at the region to be subjected to the crystallization treatment of the primary film. Examples of the holding device may include a combination of two rolls and a combination of an extruder and a winding roll. When tension such as conveyance tension is applied to the primary film by these combinations, heat shrinkage of the primary film can be suppressed at the region to be subjected to the crystallization treatment. Accordingly, when the above-described combination is used as the holding device, the primary film can be held while the primary film is conveyed in the lengthwise direction. Thus, the first substrate layer can be efficiently produced.

In the crystallization step,
the primary film is in a tensioned state in which at least two edge sides of the primary film are held as described above
the temperature of the primary film is usually set to a temperature that is equal to or higher than the glass transition temperature Tg of the crystallizable polymer and equal to or lower than the melting point Tm of the crystallizable polymer.

In the primary film kept at a temperature in the above-described range, crystallization of the crystallizable polymer proceeds. Thus, as a result of this crystallization step, a film containing the crystallized crystallizable polymer as the first substrate layer is obtained. At that time, the film is in a tensioned state while deformation of the film is prevented, and therefore the crystallization can proceed without deteriorating the smoothness of the film.

As described above, the temperature range in the crystallization step may usually be optionally set to a temperature range that is equal to or higher than the glass transition temperature Tg of the crystallizable polymer and equal to or lower than the melting point Tm of the crystallizable polymer as described above. It is particularly preferable that the temperature is set to a temperature at which the crystallization speed is increased. The temperature of the primary film in the crystallization step is preferably Tg+30° C. or higher, and more preferably Tg+40° C. or higher, and is preferably Tm−20° C. or lower, and more preferably Tm−40° C. or lower. When the temperature in the crystallization step is equal to or lower than the upper limit of the above-described range, clouding of the first substrate layer can be suppressed, and therefore a first substrate layer suitable for a case where an optically transparent first layered body is required can be obtained.

In order to set the temperature of the primary film to the above-described temperature, the primary film is usually heated. A heating device used in this case is preferably a heating device capable of increasing the atmospheric temperature of the primary film since therewith contact of the heating device with the primary film is unnecessary. Specific examples of the suitable heating device may include an oven and a heating furnace.

The treatment time when the temperature of the primary film is maintained within the above-described temperature range in the crystallization step is preferably 1 second or longer, and more preferably 5 seconds or longer, and is preferably 30 minutes or shorter, and more preferably 10 minutes or shorter. When the crystallization of the crystallizable polymer proceeds sufficiently in the crystallization step, bend resistance of the first substrate layer can be enhanced. Moreover, when the treatment time is equal to or less than the upper limit of the above-described range, clouding of the first substrate layer can be suppressed, and therefore a first substrate layer suitable for a case where an optically transparent first substrate layer is required can be obtained.

In the method for producing the first substrate layer, a further optional step may be performed in combination with the above-described crystallization step. Examples of the optional step may include a relaxation step of thermally shrinking the first substrate layer after the crystallization step to remove residual stress; and a surface-treating step of performing a surface treatment on the obtained first substrate layer.

The aforementioned production of the first substrate layer may be performed in accordance with, for example, the method described in International Publication No. 2016/067893.

### First Release Layer

The first release layer is disposed in contact with one surface or both surfaces of the first substrate layer. That is, the protective layered body of the present invention has a layer configuration of (first substrate layer)/(first release layer), a layer configuration of (first release layer)/(first substrate layer)/(first release layer) in which another first release layer is added to the layer configuration, or a layer configuration obtained by providing an additional layer on the outside of each of these layer configurations. Therefore, the protective layered body of the present invention may have one or two first release layers with respect to one first substrate layer.

The first release layer is a layer having a release property. Herein, the release property refers to a property of being easily peeled off. Specifically, the first release layer is a layer having a high release property against a layer to be protected (a resin layer (R), etc.) of the protective layered body. More specifically, the first release layer may be a layer in which the release property against the layer to be protected of the protective layered body is higher than the release property against the first substrate layer. By having such a property, the protective layered body can be easily peeled for the use of the layer to be protected.

The first release layer may be formed of a material having a release property. The material having a release property is not particularly limited, and may be appropriately selected from known materials containing a release agent. Examples of the release agent may include a silicone-based release agent and a non-silicone-based release agent such as olefin. The silicone-based release agent is preferably one obtained by curing a release agent containing a curable silicone resin. Herein, the release agent may be a release agent mainly containing a curable silicone resin, or a modified silicone type release agent that may be modified by a polymerization reaction such as a graft polymerization with an organic resin such as a urethane resin, an epoxy resin, and an alkyd resin.

As the curable silicone resin, any curing reaction type resins, such as addition type, condensation type, ultraviolet-curable, electron beam-curable, and solventless type silicone resins, may be used. Specific examples of the curable silicone resin may include KS-774, KS-775, KS-778, KS-779H, KS-847, KS-847T, KS-856, X-62-2422, and X-62-2461 manufactured by Shin-Etsu Chemical Co., Ltd.; DKQ3-202, DKQ3-203, DKQ3-204, DKQ3-205, and DKQ3-210 manufactured by Dow Corning Asia Ltd.; YSR-3022, TPR-6700, TPR-6720, and TPR-6721 manufactured by Toshiba Silicone Co., Ltd.; and SD7220, SD7226, and SD7229 manufactured by Dow Corning Toray Co., Ltd. As the release agent, one type thereof may be solely used. Alternatively, two or more types thereof may also be used in combination at any ratio.

Furthermore, a peeling controlling agent may be used in combination with the release agent in order to adjust the peeling property of the first release layer. In addition, a catalyst is usually used in combination with the release agent.

It is preferable that a material constituting the first release layer does not contain a halogen element or has a low content ratio of a halogen element. Specifically, the ratio (weight ratio) of the halogen element relative to the entire material constituting the first release layer is preferably 1,500 ppm or less, and more preferably 900 ppm or less. The lower limit of the ratio of halogen elements is ideally 0 ppm. Since the content ratio of the halogen elements falls within the range described above, the probability that the film to be protected such as the resin layer (R) is contaminated by the halogen element can be reduced. Therefore, such a material is particularly useful when the film to be protected is used in the vicinity of a member that easily deteriorates by halogen elements, such as an organic EL light-emitting body.

The first release layer may be formed, for example, by applying a coating liquid for formation of release layer onto a surface to which a release property is to be imparted, and curing the coating liquid. The coating liquid may be a composition containing a solvent in addition to the aforementioned component. As the solvent, an organic solvent such as toluene may be appropriately selected for use.

From the viewpoint of exerting a desired ability, the thickness of the release layer is preferably 0.01 μm or more, more preferably 0.03 μm or more, and further more preferably 0.05 μm or more, and is preferably 1 μm or less, more preferably 0.5 μm or less, and further more preferably 0.3 μm or less.

When the first release layer is disposed on both the front face and the rear face of the protective layered body, it is preferable that the thickness of each of the first release layers falls within the aforementioned preferable range.

### Structure and Properties of Protective Layered Body

In the protective layered body of the present invention, the first substrate layer is preferably a layer formed of a resin containing an alicyclic structure-containing crystallizable polymer, and more preferably a single layer formed of a resin containing an alicyclic structure-containing crystallizable polymer. Furthermore, the protective layered body is preferably a layer including such a first substrate layer and the first release layer, and more preferably a layer including only such a first substrate layer and the first release layer. By having such a configuration, a protective layered body that has high flexibility, that suppresses a reduction in gas barrier performance caused by damage, and that suppresses the possibility of contamination of the resin layer, as compared with a protective film that exerts a gas barrier performance by the property of an inorganic layer or of a layer of a substance containing halogen elements in the conventional technology, can be obtained.

From the viewpoint of reducing the contamination by halogen elements, it is preferable that the protective layered body does not contain a halogen element or has a low content ratio of a halogen element in the entirety thereof. Specifically, the ratio (weight ratio) of the halogen element in the entire protective layered body is preferably 1,500 ppm or less, and more preferably 900 ppm or less. The lower limit of the ratio of the halogen elements is ideally 0 ppm.

It is preferable that the protective layered body has a transparency that is at a sufficiently high level for performing a visual inspection of a defect in a layer disposed on a side opposite to an observer via the protective layered body. Specifically, the total light transmittance of the protective layered body is preferably 80% or more, more preferably 85% or more, and particularly preferably 88% or more. The total light transmittance may be measured in the wavelength range of 400 nm to 700 nm using an ultraviolet-visible spectrometer.

### Composite Layered Body

The composite layered body of the present invention includes the protective layered body of the present invention and the resin layer (R) disposed on a surface thereof to be in contact with the surface on the side of the release layer. That is, the composite layered body of the present invention has a layer configuration of (first substrate layer)/(first release layer)/(resin layer (R)) or a layer configuration in which an additional layer is further added to the outside of this layer configuration.

### Resin Layer (R)

When the resin layer (R) is left to stand in an environment at 25° C. and 50% Rh for 2 hours, the weight change ratio of the resin layer (R) is 0.5% or more. In the following description, the weight change ratio under this condition may be referred to as “weight change ratio (1)” for the sake of distinguishment thereof from weight change ratios under other measurement conditions. The weight change ratio (1) is the weight change ratio of the resin layer (R) not in a state in which the resin layer (R) is protected by the protective layered body in the composite layered body but in a state in which the resin layer (R) is not protected (e.g., a state in which the resin layer (R) is peeled from the protective layered body).

The weight change ratio (1) is preferably 1% or more, more preferably 2.5% or more, and further more preferably 5% or more. Since such a property is achieved, the resin layer (R) may be usefully applied in devices such as a light-emitting device and a display device as a sealing member having hygroscopicity for protecting a member that may be deteriorated by water in outside air. Such a resin layer (R) easily absorbs water in outside air in a storage period after production until the installation of the resin layer in the device, and the performance thereof may be deteriorated. However, when the resin layer (R) forms the composite layered body of the present invention and the surface thereof is protected by the protective layered body, the resin layer (R) can be stored for an extended period of time with suppressed deterioration, and the convenience of the resin layer (R) in production and use can be largely enhanced. The upper limit of the weight change ratio (1) is not particularly limited, but may be, for example, 10% or less.

Measurement of the weight change ratio (1) may be performed by continuous measurement of the weight of a sample in a nitrogen atmosphere under control of temperature and humidity environment using a water vapor sorption analyzer (e.g., “IGA sorp” manufactured by HIDEN ISOCHEMA). In the measurement, a film including only the resin layer (R) obtained by peeling a layer other than the resin layer (R) from the composite layered body is used as the sample.

The temperature and the humidity may be controlled as described below. The sample is first sufficiently dried and stabilized by treatments of (1-i): at 130° C. and 0% Rh for 2 hours and (1-ii): at 25° C. and 0% Rh for 2 hours immediately after the treatment (1-i). Immediately after that, the sample is allowed to stand in an environment of (1-iii): at 25° C. and 50% Rh for 2 hours.

The weight of the sample at the time when (1-ii) is terminated is recorded as weight A, the weight of the sample at the time when (1-iii) is terminated is recorded as weight B, and the weight change ratio (1) may be determined from these weights by the following equation.

$$Weight change ratio ( 1 ) ( \% ) = ( B - A ) / A \times 100$$

The resin layer (R) is preferably a layer of a resin containing a hygroscopic filler. Specifically, the resin constituting the resin layer (R) may be a resin containing a polymer and hygroscopic particles as a filler.

Examples of the polymers may include: an ethylene-α-olefin copolymer such as an ethylene-propylene copolymer; an ethylene-α-olefin-polyene copolymer; a copolymer of ethylene and an unsaturated carboxylic acid ester such as ethylene-methyl methacrylate and ethylene-butyl acrylate; a copolymer of ethylene and a vinyl fatty acid such as ethylene-vinyl acetate; a polymer of an acrylic acid alkyl ester such as ethyl acrylate, butyl acrylate, hexyl acrylate, 2-ethylhexyl acrylate, and lauryl acrylate; a diene-based copolymer such as polybutadiene, polyisoprene, an acrylonitrile-butadiene copolymer, a butadiene-isoprene copolymer, a butadiene-(meth)acrylic acid alkyl ester copolymer, a butadiene-(meth)acrylic acid alkyl ester-acrylonitrile copolymer, and a butadiene-(meth)acrylic acid alkyl ester-acrylonitrile-styrene copolymer; a butylene-isoprene copolymer; an aromatic vinyl compound-conjugated diene copolymer such as a styrene-butadiene random copolymer, a styrene-isoprene random copolymer, a styrene-butadiene block copolymer, a styrene-butadiene-styrene block copolymer, a styrene-isoprene block copolymer, and a styrene-isoprene-styrene block copolymer; a hydrogenated aromatic vinyl compound-conjugated diene copolymer such as a hydrogenated styrene-butadiene random copolymer, a hydrogenated styrene-isoprene random copolymer, a hydrogenated styrene-butadiene block copolymer, a hydrogenated styrene-butadiene-styrene block copolymer, a hydrogenated styrene-isoprene block copolymer, and a hydrogenated styrene-isoprene-styrene block copolymer; and a low-crystallizable polybutadiene, a styrene-grafted ethylene-propylene elastomer, a thermoplastic polyester elastomer, and an ethylene-based ionomer. As the polymer, one type thereof may be solely used. Alternatively, two or more types thereof may also be used in combination at any ratio.

As the polymer, a polymer selected from an aromatic vinyl compound-conjugated diene copolymer, a hydrogenated aromatic vinyl compound-conjugated diene copolymer, and combinations thereof is preferable for obtaining desired effects of the present invention.

The aromatic vinyl compound-conjugated diene copolymer is preferably an aromatic vinyl compound-conjugated diene block copolymer. The aromatic vinyl compound-conjugated diene block copolymer is preferably one selected from a styrene-butadiene block copolymer, a styrene-butadiene-styrene block copolymer, a styrene-isoprene block copolymer, a styrene-isoprene-styrene block copolymer, and mixtures thereof.

The hydrogenated aromatic vinyl compound-conjugated diene copolymer is a hydrogenated product of an aromatic vinyl compound-conjugated diene copolymer. That is, the hydrogenated aromatic vinyl compound-conjugated diene copolymer has a structure obtained by hydrogenating part or all of carbon-carbon unsaturated bonds, carbon-carbon bonds of aromatic rings, or both of them, of the main chain and the side chain of the aromatic vinyl compound-conjugated diene copolymer. However, in the present application, the hydrogenated product thereof is not limited by production methods.

Further examples of the polymer in the resin constituting the resin layer (R) may include a polymer having a polar group. The resin preferably contains, as the polymer, a polymer having a polar group. When the resin contains a polymer having a polar group, adhesion between the resin layer (R) and the device can be improved. Examples of such polar groups may include a silicon-containing group such as an alkoxysilyl group, a carbonyl-containing group such as a carboxyl group and an acid anhydride group, and an epoxy group, an amino group, and an isocyanate group. Among these, a silicon-containing group is preferable, and an alkoxysilyl group is more preferable, from the viewpoint of improving adhesion to an inorganic substance, particularly to an inorganic substance containing Si such as glasses and SiOx. Specific examples of the polymer having an alkoxysilyl group may include one or more types of polymers selected from a silane-modified product of a hydrogenated styrene-butadiene block copolymer, a silane-modified product of a hydrogenated styrene-butadiene-styrene block copolymer, a silane-modified product of a hydrogenated styrene-isoprene block copolymer, and a silane-modified product of a hydrogenated styrene-isoprene-styrene block copolymer.

More specific examples of these polymers and production methods therefor may include those described in, for example, International Publication No. 2019/151142.

The weight-average molecular weight (Mw) of the polymer constituting the resin is usually 20,000 or more, preferably 30,000 or more, and more preferably 35,000 or more, and is usually 200,000 or less, preferably 100,000 or less, and more preferably 70,000 or less. The weight-average molecular weight of the polymer may be measured as polystyrene-equivalent values by gel permeation chromatography using tetrahydrofuran as a solvent. The molecular weight distribution (Mw/Mn) of the polymer is preferably 4 or less, more preferably 3 or less, and particularly preferably 2 or less, and is preferably 1 or more. By setting the weight-average molecular weight Mw and the molecular weight distribution Mw/Mn of the polymer within the above-described ranges, mechanical strength and heat resistance of the resin layer (R) can be improved.

As the hygroscopic particles as a filler contained in the resin constituting the resin layer (R), suitable ones may be appropriately selected from various known hygroscopic particles known to exhibit good hygroscopicity. By containing such a filler, desired hygroscopicity can be easily imparted to the resin layer (R).

Examples of the material constituting the hygroscopic particles may include a basic hygroscopic agent such as a compound containing an alkali metal, an alkaline earth metal, and aluminum (such as oxide, hydroxide, or salt thereof) and not containing silicon (for example, barium oxide, magnesium oxide, calcium oxide, strontium oxide, aluminum hydroxide, hydrotalcite, and the like), an organometallic compound described in Japanese Patent Application Laid-Open No. 2005-298598 A, and a clay containing a metal oxide; and an acidic hygroscopic agent such as an inorganic compound containing silicon (for example, silica gel, nanoporous silica, zeolite) and the like.

The material of the hygroscopic particles is preferably one or more types of substances selected from the group consisting of zeolite and hydrotalcite. Zeolite has a particularly high hygroscopic capacity. The zeolite also releases water by drying, so that it can be reused. On the other hand, hydrotalcite is useful in that it has a short dispersion time when a bead mill or a wet jet dispenser is used, and can easily achieve good dispersion. As the material of the hygroscopic particles, one type thereof may be solely used. Alternatively, two or more types thereof may also be used in combination at any ratio.

The proportion of the hygroscopic particles in the resin constituting the resin layer (R) is preferably 5% by weight or more, and more preferably 10% by weight or more, and is preferably 60% by weight or less, more preferably 40% by weight or less, and still more preferably 30% by weight or less. When the proportion of the hygroscopic particles is equal to or higher than the above-described lower limit value, the effect of preventing the intrusion of water of the resin layer (R) can be enhanced. In addition, when the proportion thereof is equal to or less than the above-described upper limit value, transparency, flexibility, and processability of the resin layer (R) can be enhanced.

The resin constituting the resin layer (R) may contain an optional component in addition to the above-mentioned components. Examples of optional components may include a light stabilizer for improving weather resistance and heat resistance, an ultraviolet absorber, an antioxidant, a dispersant, a plasticizer, a lubricant, and an inorganic filler. As the optional component, one type thereof may be solely used. Alternatively, two or more types thereof may also be used in combination at any ratio.

As the dispersant, a dispersant having a function of improving dispersibility of hygroscopic particles may be appropriately selected for use. Examples of the dispersants may include a polymer dispersant. From another point of view, examples of the dispersants may include an acidic dispersant, a basic dispersant, and a neutral dispersant. More specifically, examples of the dispersant may include a basic polymer dispersant, an acidic polymer dispersant, and a neutral polymer dispersant.

Examples of polymer compounds constituting the polymer dispersant may include an anionic polymer compound, a nonionic polymer compound, a cationic polymer compound, and an amphoteric polymer compound. Examples of anionic polymer compounds may include a styrene-maleic anhydride copolymer, an olefin-maleic anhydride copolymer, a formalin conjugate of naphthalenesulfonic acid salt, a polycarboxylic acid, a polycarboxylic acid ester, a polymethylsulfonic acid salt, an acrylamide-acrylic acid copolymer, a polyacrylic acid salt, carboxymethylcellulose, and sodium alginate. Examples of nonionic polymer compounds may include a polyvinyl alcohol, a polyoxyethylene alkyl ether, a polyalkylene polyamine, a polyacrylamide, a polyoxyethylene-polyoxyethylene block copolymer, and starches. Examples of cationic polymer compounds may include a polyethyleneimine, an aminoalkyl(meth)acrylate copolymer, a polyvinylimidazoline, and chitosan.

Examples of the dispersant may include commercially available dispersants such as “ARON (registered trademark)” and “JULIMER (registered trademark)” series of TOAGOUSEI CO., LTD., “AQUALIC (registered trademark)” series of NIPPON SHOKUBAI CO., LTD., “FLOWLEN (registered trademark)” series of KYOEISHA CHEMICAL CO., LTD., “DISPARLON (registered trademark)” series of KUSUMOTO CHEMICALS, LTD., “SOKALAN (registered trademark)” series and “EFKA” series of BASF Co., “DISPERBYK (registered trademark)” series and “Anti-Terra” series of BYK Chemie Co., “SOLSPERSE (registered trademark)” series of Lubrizol Japan Limited, and “AJISPAR” series of Ajinomoto Fine-Techno Co., Inc.

More specific examples of the dispersants may include those described in International Publication No. 2019/151142.

As the dispersant, one type out of the above-mentioned ones may be solely used. Alternatively, two or more types thereof may also be used in combination at any ratio.

The amount of the dispersant is preferably 0.1 part by weight or more, more preferably 7 parts by weight or more, and even more preferably 10 parts by weight or more, and is preferably 1,000 parts by weight or less, more preferably 70 parts by weight or less, and even more preferably 50 parts by weight or less, relative to 100 parts by weight of the hygroscopic particles. By setting the amount of the dispersant to be equal to or greater than the above-described lower limit value, good dispersion of the hygroscopic particles can be achieved, and the internal haze can be lowered to achieve high transparency. By setting the amount of the dispersant to be equal to or less than the above-described upper limit value, it is possible to suppress a decrease in adhesion between the resin layer (R) and another member caused by the dispersant.

Suitable examples of the plasticizer may include a hydrocarbon-based oligomer; an organic acid ester-based plasticizer such as a monobasic organic acid ester and a polybasic organic acid ester; a phosphoric acid ester-based plasticizer such as an organic phosphoric acid ester-based plasticizer and an organic phosphorous acid ester-based plasticizer; and combinations thereof.

Specific examples of the hydrocarbon-based oligomer may include a polyisobutylene, a polybutene, a poly-4-methylpentene, a poly-1-octene, an ethylene-α-olefin copolymer, a polyisoprene, an alicyclic hydrocarbon, other aliphatic hydrocarbons, an aromatic vinyl compound-conjugated diene copolymer, hydrogenated products of the above-described compounds, and a hydrogenated product of an indene-styrene copolymer. Among these, a polyisobutylene, a polybutene, a hydrogenated polyisobutylene, and a hydrogenated polybutene are preferable.

The amount of the plasticizer is preferably 1 part by weight or more, more preferably 5 parts by weight or more, and still more preferably 10 parts by weight or more, and is preferably 60 parts by weight or less, and more preferably 50 parts by weight or less, relative to 100 parts by weight of the resin as the main component of the polymer. When the amount of the plasticizer is equal to or greater than the above-described lower limit, a sufficient plasticizing effect can be obtained, and bonding upon installing the resin layer (R) is provided in a device can be easily performed at a low temperature. When the amount of the plasticizer is less than or equal to the above-described upper limit, bleed-out of the plasticizer, which occurs when the amount of the plasticizer exceeds the above-described parts by weight, can be suppressed, and the adhesiveness between the resin layer (R) and the bonding target can be enhanced.

It is preferable that a resin layer (R) does not contain a halogen element or has a low content ratio of a halogen element. Specifically, the ratio (weight ratio) of the halogen element relative to the entire resin layer (R) is preferably 1,500 ppm or less, and more preferably 900 ppm or less. The lower limit of the ratio of halogen elements is ideally 0 ppm. Since the content ratio of the halogen elements falls within the range described above, the probability that the resin layer (R) is contaminated by the halogen element can be reduced, and therefore, the resin layer (R) is particularly useful when the resin layer (R) is used in the vicinity of a member that is easily deteriorated by halogen elements, such as an organic EL light-emitting body.

The method of forming the resin layer (R) is not particularly limited, and a general method of forming a resin layer may be adopted. For example, the resin layer (R) may be formed by preparing a dispersion liquid containing the above-mentioned components and a solvent, applying the dispersion liquid onto the surface of the protective layered body on the surface of the release layer side, and drying the dispersion liquid to volatilize the solvent.

Examples of solvents may include a substance which is liquid at normal temperatures (preferably 25° C.). Specific examples thereof may include cyclohexane, hexane, toluene, benzene, N,N-dimethylformamide, tetrahydrofuran, decahydronaphthalene, trimethylbenzene, methylcyclohexane, ethylcyclohexane, cyclooctane, cyclodecane, normal octane, dodecane, tridecane, tetradecane, cyclododecane and mixtures thereof.

### Additional Layer: Thin Film Glass

In an example, the composite layered body of the present invention further includes a thin film glass that is disposed on the resin layer (R) on a side opposite to the first release layer and that has a thickness of 25 to 100 μm. That is, the composite layered body in this aspect has a layer configuration of (first substrate layer)/(first release layer)/(resin layer (R))/(thin film glass) or a layer configuration in which an additional layer is further added to the outside of this layer configuration.

In general, a glass plate such as a thin film glass has a sufficient gas barrier performance. When the resin layer (R) is used as a constituent element of a device such as an optical device, the resin layer (R) is usually used in a state of being bonded to the thin film glass that is another constituent element. In the composite layered body of the present invention including such a thin film glass, one surface of the resin layer (R) is protected by the thin film glass and another surface of the resin layer (R) is protected by the protective layered body (i.e., (first substrate layer)/(first release layer)). Therefore, in the layered body, both surfaces of the resin layer (R) are protected. Accordingly, satisfactory storage can be achieved in a storage period after the production of the composite layered body until the installation thereof in the device, and a combination of the thin film glass and the resin layer (R) can be easily installed in the device.

### Additional Layer: Counter Protective Layered Body: Double-Side Protective Composite Layered Body

In an example, the composite layered body of the present invention further includes a counter protective layered body that is disposed on the resin layer (R) on a side opposite to the first release layer. The counter protective layered body is a layered body including a second substrate layer and a second release layer disposed in contact with one surface or both surfaces of the second substrate layer, and the surface of the counter protective layered body on the side of the second release layer is disposed in contact with the resin layer (R). In the present application, among composite layered bodies, a composite layered body including a constituent element such as a counter protective layered body or a thin layer glass in addition to the protective layered body may be particularly referred to as a double-side protective composite layered body, for the sake of the description. The double-side protective composite layered body including a counter protective layered body has a layer configuration of (first substrate layer)/(first release layer)/(resin layer (R))/(second release layer)/(second substrate layer) or a layer configuration in which an additional layer is further added to the outside of this layer configuration.

The second substrate layer may be a layer containing a polymer and having a water vapor transmission rate at 40° C. and 90% Rh of smaller than 1 g/m²/day when the second substrate layer is assumed to have a thickness of 100 μm. When the double-side protective composite layered body is formed using such a second substrate layer in combination with the first substrate layer, satisfactory storage can be achieved in a storage period after the production of the composite layered body until the installation thereof in the device. In addition, the resin layer (R) is not limited to the layer for provision on the surface of the thin film glass, but the resin layer (R) can be easily disposed on the surface of any constituent element of the device.

Specific examples of the second substrate layer and the second release layer may include those that are the same as the specific examples of the first substrate layer and the first release layer as described above. In the double-side protective composite layered body, the second substrate layer and the second release layer may be different from the first substrate layer and the first release layer, respectively, but are preferably the same as the first substrate layer and the first release layer, respectively, from the viewpoint of production easiness and stable expression of gas barrier performance. Specifically, it is preferable that a layered body including a substrate layer and a release layer is prepared and cut into a plurality of sheets of layered bodies having an appropriate size, and a double-side protective composite layered body is formed using one sheet of the layered bodies as a protective layered body including a first substrate layer and a first substrate layer and another one sheet of the layered bodies as a counter protective layered body including a second substrate layer and a second substrate layer.

The double-side protective composite layered body and the composite layered body including the protective layered body and the thin film glass achieve an effect of achieving a good protection of the resin layer (R). Such an effect can be evaluated by the measurement of the weight change ratio of the resin layer (R) in the double-side protective composite layered body. Hereinafter, the weight change ratio under this condition may be referred to as “weight change ratio (2)”. The weight change ratio (2) is the weight change ratio of the resin layer (R) in a state in which the resin layer (R) is protected by the protective layered body in the composite layered body, and therefore the weight change ratio (2) is different from the weight change ratio (1) in this point.

The weight change ratio (2) may be measured using the same device as the device used in the measurement of the weight change ratio (1). In this case, measurement is performed using three measurement samples: a film including only the resin layer (R), only the protective layered body, and the double-side protective composite layered body.

In the measurement for the film including only the resin layer (R) as a sample, the weight A and the weight B are recorded by the same manner as that in the measurement of the weight change ratio (1) described above.

In the measurement for only the protective layered body as a sample, the sample is first sufficiently dried and stabilized by treatments of (2-1-i): at 130° C. and 0% Rh for 2 hours and (2-1-ii): at 25° C. and 0% Rh for 2 hours immediately after (2-1-i). Immediately after that, the sample was allowed to stand in an environment of (2-1-iii): at 25° C. and 50% Rh for 2 hours. The weight of the sample at the time when (2-1-ii) is terminated is recorded as weight C, and the weight of the sample at the time when (2-1-iii) is terminated is recorded as weight D.

In the measurement for the double-side protective composite layered body as a sample, the sample is first sufficiently dried and stabilized by treatments of (2-2-i): at 130° C. and 0% Rh for 2 hours and (2-2-ii): at 25° C. and 0% Rh for 2 hours immediately after (2-2-i). Immediately after that, the sample was allowed to stand in an environment of (2-2-iii): at 25° C. and 50% Rh for 2 hours. The weight of the sample at the time when (2-2-ii) is terminated is recorded as weight E, and the weight of the sample at the time when (2-2-iii) is terminated is recorded as weight F.

From these, the weight change ratio (2) may be determined by the following expression.

$$Weight change ratio ( 2 ) ( \% ) = \{ ( F - E ) - 2 \times ( D - C ) \} / A \times 100$$

In the double-side protective composite layered body of the present invention, it is possible that the weight change ratio (2) is as small as 0.2% or less.

### EXAMPLES

Hereinafter, the present invention will be specifically described by illustrating Examples. However, the present invention is not limited to the Examples described below. The present invention may be optionally modified for implementation without departing from the scope of claims of the present invention and its equivalents. In the following description, “%” and “part” representing quantity are on the basis of weight, unless otherwise specified.

### Evaluation Method

### Method for Measuring Hydrogenation Ratio of Polymer

The hydrogenation ratio of the polymer was measured by ¹H-NMR measurement using ortho-dichlorobenzene-d₄ as a solvent at 145° C.

### Method for Measuring Weight-Average Molecular Weight (Mw) and Number-Average Molecular Weight (Mn) of Polymer

The weight-average molecular weight (Mw) and number-average molecular weight (Mn) of the polymer were measured as a polystyrene-equivalent value using a gel permeation chromatography (GPC) system (“HLC-8320” manufactured by Tosoh Corporation). In the measurement, an H-type column (manufactured by Tosoh Corporation) was used as a column, and tetrahydrofuran was used as a solvent. The temperature during the measurement was 40° C.

### Method for Measuring Racemo Diad Ratio of Polymer

The racemo diad ratio of the polymer was measured as described below.

Adopting an inverse-gated decoupling method, ¹³C-NMR measurement of the polymer was performed using ortho-dichlorobenzene-d₄ as a solvent at 200° C. In the result of this ¹³C-NMR measurement, a signal at 43.35 ppm derived from a meso diad and a signal at 43.43 ppm derived from a racemo diad were identified with a peak at 127.5 ppm of ortho-dichlorobenzene-d₄ as a reference shift. The racemo diad ratio of the polymer was determined on the basis of the intensity ratio of these signals.

### Method for Measuring Glass Transition Temperature Tg, Melting Point Tm, and Crystallization Peak Temperature Tpc of Resin Material

The glass transition temperature Tg and the melting point Tm of the resin material were measured as described below.

A resin material as a sample was molten by heating, and the molten product was quickly cooled with dry ice. Subsequently, the glass transition temperature Tg, the melting point Tm, and the crystallization peak temperature Tpc of this sample were measured using a differential scanning calorimeter (DSC) at a temperature increasing rate of (temperature increasing mode) of 10° C./min.

### Method for Measuring Crystallization Degree of Polymer

The crystallization degree (%) of the polymer was measured by an X-ray diffraction method.

### Method for Measuring Thickness of Film

The thickness (μm) of the film was measured using a contact-type web thickness meter (“RC-101” manufactured by Maysun Corporation).

### Method for Measuring Total Light Transmittance of Film

The film was cut into a size of 50 mm×50 mm, and the total light transmittance of the film was measured using a haze meter (“NDH4000” manufactured by Nippon Denshoku Industries Co., Ltd.).

### Method for Measuring Water Vapor Transmission Rate WVTR of Film

A water vapor transmission rate WVTR (unit: g/m²/day) was measured under conditions of a temperature of 40° C. and a relative humidity of 90% using a water vapor transmission rate tester (L80 series manufactured by Lyssy).

When a protective layered body including only a substrate layer and a release layer is a measurement sample, the water vapor transmission rate of the release layer is very high, and therefore the presence of the release layer can be ignored in the measurement of the water vapor transmission rate. Accordingly, the water vapor transmission rate of the protective layered body can be considered to be the same as the water vapor transmission rate of only the substrate layer.

Subsequently, the water vapor transmission rate WVTR (100 μm) (unit: g/m²/day) of a film, when the substrate layer was assumed to have a thickness of 100 μm, was determined from the measured WVTR value and the thickness of the substrate layer (unit: μm) by the following expression.

$$WVTR ( 100 μm ) = ( ( thickness of substrate layer ) / 100 ) \times WVTR$$

### Method for Measuring Weight Change Ratios (1) and (2)

The weight of a sample was continuously measured in a nitrogen atmosphere under control of temperature and humidity environment using a water vaper sorption analyzer (“IGA sorp” manufactured by HIDEN ISOCHEMA). As measurement, measurement using a film including only a resin layer (R) as a sample, measurement using a protective layered body as a sample, and measurement using a double-side protective composite layered body as a sample were each performed. The temperature and the humidity were controlled as described below.

### Measurement for Film Including Only Resin Layer (R) as Sample

(1-i): 130° C., 0% Rh, 2 hours
(1-ii): 25° C., 0% Rh, 2 hours immediately after (1-i)
(1-iii): 25° C., 50% Rh, 2 hours immediately after (1-ii)

The weight of the sample at the time when (1-ii) was terminated was recorded as weight A, and the weight of the sample at the time when (1-iii) was terminated was recorded as weight B. From these, the weight change ratio (1) was determined by the following expression.

$$Weight change ratio ( 1 ) ( \% ) = ( B - A ) / A \times 100$$

### Measurement for Only Protective Layered Body as Sample

(2-1-i): 130° C., 0% Rh, 2 hours
(2-1-ii): 25° C., 0% Rh, 2 hours immediately after (2-1-i)
(2-1-iii): 25° C., 50% Rh, 2 hours immediately after (2-1-ii)

The weight of the sample at the time when (2-1-ii) was terminated was recorded as weight C, and the weight of the sample at the time when (2-1-iii) was terminated was recorded as weight D.

### Measurement for Double-Side Protective Composite Layered Body as Sample

(2-2-i): 130° C., 0% Rh, 2 hours
(2-2-ii): 25° C., 0% Rh, 2 hours immediately after (2-2-i)
(2-2-iii): 25° C., 50% Rh, 2 hours immediately after (2-2-ii)

The weight of the sample at the time when (2-2-ii) was terminated was recorded as weight E, and the weight of the sample at the time when (2-2-iii) was terminated was recorded as weight F. From these, the weight change ratio (2) was determined by the following expression.

$$Weight change ratio ( 2 ) ( \% ) = \{ ( F - E ) - 2 \times ( D - C ) \} / A \times 100$$

### Production Example 1. Production of Crystallizable Resin A

A metal pressure-resistant reaction vessel was sufficiently dried, and then inside air was replaced with nitrogen. To this pressure-resistant reaction vessel, 154.5 parts of cyclohexane, 42.8 parts (the amount of dicyclopentadiene was 30 parts) of a 70% solution of dicyclopentadiene (endo-isomer containing rate: 99% or more) in cyclohexane, and 1.8 parts of 1-hexene were added, and the mixture was heated to 53° C.

To a solution in which 0.014 part of tetrachlorotungsten phenylimide (tetrahydrofuran) complex was dissolved in 0.70 part of toluene, 0.061 part of a 19% solution of diethylaluminum ethoxide/n-hexane was added, and the mixture was stirred for 10 minutes to prepare a catalyst solution. This catalyst solution was added to the above-described pressure-resistant reaction vessel to initiate a ring-opening polymerization reaction. After that, the reaction was allowed to proceed for 4 hours while the temperature was kept at 53° C., to obtain a solution of a ring-opening polymer of dicyclopentadiene.

The number-average molecular weight (Mn) and weight-average molecular weight (Mw) of the obtained ring-opening polymer of dicyclopentadiene were 8,830 and 29,800, respectively, and the molecular weight distribution (Mw/Mn) calculated from these values was 3.37.

To 200 parts of the obtained solution of the ring-opening polymer of dicyclopentadiene, 0.037 part of 1,2-ethanediol was added as a terminator, and the mixture was heated to 60° C. and stirred for 1 hour to terminate the polymerization reaction. To this solution, 1 part of hydrotalcite-like compound (“KYOWAAD (registered trademark) 2000” manufactured by Kyowa Chemical Industry Co., Ltd.) was added, and the mixture was heated to 60° C. and stirred for 1 hour. After that, 0.4 part of a filtration aid (“Radiolite (registered trademark) #1500” manufactured by Showa Chemical Industry Co., Ltd.) was added, and the absorbent and the solution were separated by filtration through a PP pleated cartridge filter (“TCP-HX” manufactured by Advantec Toyo Kaisha, Ltd.).

To 200 parts (polymer amount: 30 parts) of the filtered solution of the ring-opening polymer of dicyclopentadiene, 100 parts of cyclohexane and 0.0043 part of chlorohydridocarbonyl tris(triphenylphosphine) ruthenium were added, and a hydrogenation reaction was allowed to proceed under a hydrogen pressure of 6 MPa at 180° C. for 4 hours. As a result, a reaction liquid containing a hydrogenated product of the ring-opening polymer of dicyclopentadiene was obtained. This reaction liquid became a slurry solution by precipitation of the hydrogenated product.

The hydrogenated product and the solution contained in the above-described reaction liquid were separated using a centrifugal separator, and dried under reduced pressure at 60° C. for 24 hours to obtain 28.5 parts of the hydrogenated product of the ring-opening polymer of dicyclopentadiene having crystallizability. It was confirmed that this hydrogenated product had a hydrogenation ratio of 99% or more. The glass transition temperature Tg was 97° C., the melting point Tm was 266° C., the crystallization peak temperature Tpc was 136° C., and the racemo diad ratio was 89%.

Subsequently, 1.1 parts of an antioxidant (tetrakis(methylene-3-(3′,5′-di-t-butyl-4′-hydroxyphenyl)propionate)methane; “Irganox (registered trademark) 1010” manufactured by BASF Japan Ltd.) was mixed with 100 parts of the obtained hydrogenated product of the ring-opening polymer of dicyclopentadiene, and the mixture was put into a twin-screw extruder (“TEM-37B” manufactured by Toshiba Machine Co., Ltd.) having four die holes each having an inner diameter of 3 mm. The resin was molded by hot-melt extrusion molding using the above-described twin-screw extruder to obtain a molded body having a strand shape. The molded body was finely cut using a strand cutter to obtain pellets of a crystallizable resin A. The operation conditions of the above-described twin-screw extruder are shown below.
Barrel set temperature: 270° C. to 280° C.
Die set temperature: 250° C.
Screw rotation speed: 145 rpm

### Production Example 2. Production of Resin Pellet for Formation of Resin Layer (R)

A hydrogenated product of a block copolymer (hydrogenated block copolymer) was produced using styrene as an aromatic vinyl compound and isoprene as a linear conjugated diene compound by the following procedure. The produced hydrogenated product of a block copolymer had a triblock structure in which a polymer block (A) was bonded to each end of a polymer block (B).

In a reaction vessel equipped with a stirrer, of which inside air was sufficiently replaced with nitrogen, 256 parts of dehydrated cyclohexane, 25.0 parts of dehydrated styrene, and 0.615 part of n-dibutyl ether were placed. While the mixture was stirred at 60° C., 1.35 parts of n-butyl lithium (15% cyclohexane solution) was added thereto for initiating polymerization. The reaction was allowed to proceed at 60° C. for 60 minutes with stirring. At this point, the polymerization conversion rate was 99.5% (the polymerization conversion rate was measured by gas chromatography, and hereinafter the same applies).

Subsequently, 50.0 parts of dehydrated isoprene was added thereto, and stirring of the mixture was continued at the same temperature for 30 minutes. The polymerization conversion rate at this point was 99%.

After that, 25.0 parts of dehydrated styrene was further added thereto, and the mixture was stirred at the same temperature for 60 minutes. The polymerization conversion rate at this point was almost 100%.

Subsequently, 0.5 part of isopropyl alcohol was added to the reaction liquid to terminate the reaction. Thus, a solution (i) containing a block copolymer was obtained.

The weight-average molecular weight (Mw) of the block copolymer in the obtained solution (i) was 44,900, and the molecular weight distribution (Mw/Mn) thereof was 1.03 (they were measured as a polystyrene-equivalent value by gel permeation chromatography using tetrahydrofuran as a solvent, and hereinafter the same applies).

Subsequently, the solution (i) was transferred to a pressure-resistant reaction vessel equipped with a stirrer, 4.0 parts of a silica-alumina supporting nickel catalyst (E22U, nickel supporting amount: 60%; manufactured by Nikki Chemical Industry Corporation) as a hydrogenation catalyst and 350 parts of dehydrated cyclohexane were added to the solution (i) and mixed. The inside air of the reaction vessel was replaced with a hydrogen gas, and hydrogen was further supplied while the solution was stirred. Thus, a hydrogenation reaction was allowed to proceed at a temperature of 170° C. and a pressure of 4.5 MPa for 6 hours to hydrogenate the block copolymer. As a result, a solution (iii) containing a hydrogenated product (ii) of the block copolymer was obtained. The weight-average molecular weight (Mw) of the hydrogenated product (ii) in the solution (iii) was 45,100, and the molecular weight distribution (Mw/Mn) thereof was 1.04.

After termination of the hydrogenation reaction, the solution (iii) was filtered to remove the hydrogenation catalyst. After that, to the filtered solution (iii), 1.0 part of xylene solution in which 0.1 part of 6-(3-(3-t-butyl-4-hydroxy-5-methylphenyl)propoxy)-2,4,8,10-tetrakis-t-butyldibenzo(d,f)(1.3.2) dioxaphosphepin (“Sumilizer (registered trademark) GP” manufactured by Sumitomo Chemical Co., Ltd., hereinafter referred to as “antioxidant A”) as a phosphorus-based antioxidant was dissolved was added and dissolved to obtain a solution (iv).

Subsequently, the solution (iv) was filtered through a Zeta Plus (registered trademark) filter 30H (manufactured by CUNO, Inc., pore diameter: 0.5 μm to 1 μm), and successively filtered through another filter formed of metal fibers (manufactured by Nichidai Corporation, pore diameter: 0.4 μm) to remove a minute solid content. From the filtered solution (iv), cyclohexane and xylene as the solvents, and other volatile components were removed at a temperature 260° C. and a pressure of 0.001 MPa or less using a cylindrical concentrating and drying device (product name “Kontro” manufactured by Hitachi, Lid.). From a die directly connected to the above-described concentrating and drying device, the solid content was extruded into a strand shape in a molten state, and the extruded product was cooled and cut using a pelletizer to obtain 85 parts of pellets (v) containing the hydrogenated product of the block copolymer and the antioxidant A. The weight-average molecular weight (Mw) of the hydrogenated product of the block copolymer (hydrogenated block copolymer) in the obtained pellets (v) was 45,000, and the molecular weight distribution (Mw/Mn) thereof was 1.08. The hydrogenation ratio measured by ¹H-NMR was 99.9%.

From the pellets (v), a film-shaped test piece was produced, and the glass transition temperature Tg thereof was measured. The Tg was 130° C.

To 100 parts of the pellets (v), 2.0 parts of vinyltrimethoxysilane and 0.2 part of di-t-butyl peroxide were added to obtain a mixture. This mixture was kneaded using a twin-screw extruder at a barrel temperature of 210° C. for a residence time of 80 seconds to 90 seconds. The kneaded mixture was extruded and cut using a pelletizer to obtain pellets (vi) of a silane-modified product of the hydrogenated block copolymer that were resin pellets for formation of a resin layer (R). The glass transition temperature Tg of the pellets (vi) was measured. The Tg was 124° C.

### Example 1

### (1-1. Substrate Layer)

The pellets of the crystallizable resin A obtained in Production Example 1 were supplied to a hot-melt extrusion film-molding machine equipped with a T-die. The crystallizable resin A was extruded from the T-die and wound at a rate of 8 m/min into a roll using this film-molding machine. Thus, a long-length primary film (width: 1,340 mm) was produced. The operation conditions of the above-described film-molding machine are shown below.
Barrel set temperature: 280° C. to 290° C.
Die temperature: 270° C.

The thickness of the obtained primary film was 50 μm.

The obtained primary film was supplied to a tenter stretching machine equipped with clips. Both ends of the film in the width direction were gripped with the clips of the tenter stretching machine and drawn, and the film was stretched in the film width direction at a stretching temperature of 125° C. and a stretching ratio of 1.33. After that, while the distance between the clips was remained in a fixed width, the film was passed through an oven at 170° C. over 30 seconds to perform a crystallization treatment. Subsequently, both ends of the film in the width direction were cut. As a result, a stretched film having a width of 1,300 mm and a thickness of 38 μm was obtained for use as a first substrate layer. The crystallization degree was measured using the resulting stretched film as a sample. The crystallization degree was 42%.

### (1-2. Coating Liquid for Formation of Release Layer)

10 parts of a curable silicone resin (“LTC761” manufactured by Dow Corning Toray Co., Ltd.) and 0.3 part of a platinum catalyst (“SRX212” manufactured by Dow Corning Toray Co., Ltd.) were mixed and then diluted with toluene so that the solid content concentration became 2% to prepare a coating liquid for formation of release layer.

### (1-3. Protective Layered Body (First Substrate Layer/First Release Layer))

The coating liquid for formation of release layer obtained in (1-2) was applied onto a surface of the stretched film obtained in (1-1) to form a layer of the coating liquid. The layer of the coating liquid was subjected to a drying treatment and a curing treatment by heating in an oven at 120° C. for 3 minutes. As a result, a protective layered body 1 including a first substrate layer formed of the stretched film and a first release layer disposed on the surface of the first substrate layer was obtained.

The weight per unit area of the first release layer of the protective layered body 1 was 0.12 g/m². The water vapor transmission rate WVTR of the protective layered body 1 was measured. The WVTR was 0.7 g/m²/day. The water vapor transmission rate of the release layer is very high, and therefore the presence of the release layer can be ignored in the measurement of the water vapor transmission rate. Accordingly, the water vapor transmission rate of the protective layered body 1 can be considered to be the same as the water vapor transmission rate of only the substrate layer. The water vapor transmission rate WVTR (100 μm), when the substrate layer was assumed to have a thickness of 100 μm, was converted from the thickness of the substrate layer and found to be 0.27 g/m²/day. The total light transmittance of the protective layered body 1 was 91%.

### (1-4. Dispersion Liquid for Formation of Resin Layer (R))

50 parts of the pellets (vi) for formation of resin layer (R) obtained in Production Example 2, 20 parts of polybutene (Nisseki Polybutene LV-100, manufactured by Nippon Oil Corporation), 30 parts of hydrotalcite particles (primary particle diameter: 100 nm), 3 parts of a dispersant (SOLSEPERSE21000, manufactured by Lubrizol Japan Limited), and 150 parts of ethylcyclohexane were mixed, and the hydrotalcite particles were crushed using a wet-type jet dispenser to prepare a dispersion liquid for formation of resin layer (R).

### (1-5. Double-Side Protective Composite Layered Body (First Substrate Layer/First Release Layer/Resin Layer (R)/Second Release Layer/Second Substrate Layer))

The dispersion liquid obtained in (1-4) was applied onto the surface of the protective layered body 1 obtained in (1-3) on the side of the release layer to form a coating film. The thickness of the coating film was adjusted so that the thickness after drying was 30 μm. The coating film of the particle dispersion liquid was dried at 110° C. for 3 minutes, and further dried in a nitrogen atmosphere at 130° C. for 2 hours. Immediately after that, the surface of another protective layered body 1 on the side of the release layer was laminated as a counter protective layered body (i.e., (second release layer)/(second substrate layer)) on the coating film of the particle dispersion liquid. By this operation, a double-side protective composite layered body having a layer configuration of (first substrate layer)/(first release layer)/(resin layer (R))/(second release layer)/(second substrate layer) was obtained.

### (1-6. Evaluation)

For the double-side protective composite layered body itself obtained in (1-5), the layered body obtained in (1-3), and a film including only the resin layer (R) that was obtained by peeling both (the first substrate layer)/(the first release layer) and (the second release layer)/(the second substrate layer) from the double-side protective composite layered body obtained in (1-5) as samples, the weight change ratio (1) of the resin layer (R) and the weight change ratio (2) of the resin layer (R) in the double-side protective composite layered body were measured. The weight change ratio (1) was 5%, and the weight change ratio (2) was less than 0.1%.

The appearance of the double-side protective composite layered body was observed with the naked eye, and whether irregular substances (substances present in the resin layer due to contaminant of minute substances from the outside, deterioration of the materials, or other causes, the substances having properties different from those of another portion of the resin layer) in the resin layer (R) can be visually recognized was evaluated. As a result, the irregular substances in the resin layer (R) was able to be visually recognized in both the observation through the first substrate layer and the first release layer and the observation through the second substrate layer and the second release layer.

### Example 2

### (2-1. Coating Liquid for Formation of Release Layer)

10 parts of a curable silicone resin (“KS847” manufactured by Shin-Etsu Chemical Co., Ltd.) and 0.15 part of a platinum catalyst (“PL-50T” manufactured by Shin-Etsu Chemical Co., Ltd.) were mixed and then diluted with toluene so that the solid content concentration became 2% to prepare a coating liquid for formation of release layer.

### (2-2. Protective Layered Body and Double-Side Protective Composite Layered Body)

A protective layered body and a double-side protective composite layered body were obtained and evaluated by the same operations as those of (1-1) and (1-3) to (1-6) of Example 1 except for the following changes.
In the preparation of the substrate layer in (1-1), the winding rate during extrusion of the crystallizable resin A from the T-die was changed from 8 m/min to 12 m/min.
In the production of the protective layered body in (1-3), the coating liquid for formation of release layer obtained in (2-1) was used instead of the coating liquid for formation of release layer obtained in (1-2).

### Example 3

### (3-1. Substrate Layer)

Pellets of an amorphous resin B (“ZEONEX790R” manufactured by ZEON Corporation) containing 99% by weight of an amorphous cyclic olefin-based polymer (glass transition temperature Tg: 163° C.) were prepared. The pellets of the crystallizable resin A obtained in Production Example 1 and the pellets of the amorphous resin B were mixed at a weight ratio of the crystallizable resin A: the amorphous resin B=7:3, put into a twin-screw kneading extruder (the same as one used in Production Example 1), and kneaded with the twin-screw in the extruder. After that, the mixture was extruded into a strand shape from the extruder and cut using a strand cutter to obtain pellets of the mixed resin. The operation conditions of the twin-screw kneading extruder are shown below.
Barrel set temperature: 275° C. to 280° C.
Die set temperature: 275° C.
Screw rotation speed: 200 rpm

The glass transition temperature Tg of the resultant mixed resin was 104° C., the melting point Tm thereof was 264° C., and the crystallization peak temperature Tpc thereof was 180° C.

### (3-2. Protective Layered Body and Double-Side Protective Composite Layered Body)

A protective layered body and a double-side protective composite layered body were obtained and evaluated by the same operations as those of Example 1 except for the following changes.
In the preparation of the substrate layer in (1-1), the pellets of the mixed resin obtained in (3-1) were used instead of the pellets of the crystallizable resin A obtained in Production Example 1.
In the preparation of the substrate layer in (1-1), the temperature of the crystallization treatment was changed from 170° C. to 180° C.

### Comparative Example 1

A commercially available release PET film (“HY-US20” manufactured by Higashiyama Film Co., Ltd., hereinafter the same applies) was prepared. The release PET film was a product in which one surface of the PET film was coated with a silicone release layer.

The particle dispersion liquid obtained in (1-4) of Example 1 was applied onto the surface of the release PET film on the side of the release layer to form a coating film. The thickness of the coating film was adjusted so that the thickness after drying became 30 μm. The coating film of the particle dispersion liquid was dried at 110° C. for 3 minutes, and further dried in a nitrogen atmosphere at 130° C. for 2 hours. Immediately after that, the surface of another release PET film on the side of the release layer was laminated on the coating film of the particle dispersion liquid. By this operation, a double-side protective composite layered body having a layer configuration of (PET film)/(release layer)/(resin layer (R))/(release layer)/(PET film) was obtained. The obtained double-side protective composite layered body was evaluated by the same operations as those of (1-6) of Example 1.

### Comparative Example 2

On the surface of a commercially available release PET film on a side with no release layer, aluminum was sputtered using a sputtering device to form an aluminum layer having a thickness of 100 nm. Thus, a protective layered body C2 having a layer configuration of (aluminum layer)/(PET film)/(release layer) was obtained.

The particle dispersion liquid obtained in (1-4) of Example 1 was applied onto the surface of the protective layered body C2 on the side of the release layer to form a coating film. The thickness of the coating film was adjusted so that the thickness after drying became 30 μm. The coating film of the particle dispersion liquid was dried at 110° C. for 3 minutes, and further dried in a nitrogen atmosphere at 130° C. for 2 hours. Immediately after that, the surface of another protective layered body C2 on the side of the release layer was laminated on the coating film of the particle dispersion liquid. By this operation, a double-side protective composite layered body having a layer configuration of (aluminum layer)/(PET film)/(release layer)/(resin layer (R))/(release layer)/(PET film)/(aluminum layer) was obtained. The obtained double-side protective composite layered body was evaluated by the same operations as those of (1-6) of Example 1.

### Comparative Example 3

A double-side protective composite layered body was obtained and evaluated by the same operations as those of Comparative Example 2 except that the condition of sputtering was changed, and the thickness of the aluminum layer was changed from 100 nm to 50 nm.

The results in Examples and Comparative Examples are shown in Table 1.

TABLE 1

| | | | | Comp. | Comp. | Comp. |
|---|---|---|---|---|---|---|
| | Ex. 1 | Ex. 2 | Ex. 3 | Ex. 1 | Ex. 2 | Ex. 3 |
| Substrate | Crystallizable | Crystallizable | Mixed | PET | AL | AL |
| layer | resin A | resin A | resin | | deposited | deposited |
| | | | | | PET | PET |
| Substrate | 38 | 25 | 50 | 38 | 38 | 38 |
| layer | | | | | | |
| thickness | | | | | | |
| (μm) | | | | | | |
| WVTR(g/ | 0.7 | 1.1 | 1.8 | 13.4 | 0.6 | 1.1 |
| m2/day) | | | | | | |
| WVTR | 0.27 | 0.28 | 0.9 | 5.1 | 5.1 | 5.1 |
| (100 μm) | | | | | | |
| (g/m2/day) | | | | | | |
| Total light | 91 | 91 | 91 | 89 | 0.1> | 0.7 |
| transmittance | | | | | | |
| (%) | | | | | | |
| Weight change | 5 | 5 | 5 | 5 | 5 | 5 |
| ratio (1) | | | | | | |
| (%) | | | | | | |
| Weight change | 0.1> | 0.1> | 0.15 | 1.1 | 0.1> | 0.1> |
| ratio (2) | | | | | | |
| (%) | | | | | | |
| Irregular | Observable | Observable | Observable | Observable | Not | Not |
| substance | | | | | observable | observable |
| observation | | | | | | |

Observed: The observer was able to visually recognize irregular substances in the resin layer (R) in both the observation from one surface side (observation through the first substrate layer and the first release layer) and the observation from the other surface side (observation through the second substrate layer and the second release layer).
Not observed: The observer was unable to visually recognize irregular substances in the resin layer (R) in both the observation from the one surface side and the observation from the other surface side.

From these results, it is found that, in Examples of the present application, the double-side protective composite layered body having the resin layer (R) can have a weight change ratio (2) that is suppressed to a sufficiently low value, even though the resin layer (R) has a weight change ratio (1) that is as high as 5% or more. The double-side protective composite layered bodies of Examples include substrate layers each having a thickness of 25 to 50 μm, the substrate layers themselves exert a gas barrier performance, and the double-side protective composite layered bodies are configured so as not to have another gas barrier layer such as an inorganic layer. Accordingly, the double-side protective composite layered bodies can secure sufficient flexibility with satisfactory moisture absorption being kept, and even if they are a long-length film, they can be stored in a thin packing form of a film roll.

1. A protective layered body comprising: a first substrate layer; and a first release layer disposed in contact with one surface or both surfaces of the first substrate layer, wherein
the first substrate layer is a layer formed of a resin containing a polymer and having a water vapor transmission rate at 40° C. and 90% Rh of smaller than 1 g/m²/day when the first substrate layer is assumed to have a thickness of 100 μm.

2. The protective layered body according to claim 1, wherein the polymer is an alicyclic structure-containing crystallizable polymer.

3. A composite layered body comprising:
the protective layered body according to claim 1; and
a resin layer (R) disposed on the protective layered body to be in contact with a surface thereof on a side of the release layer, wherein
when the resin layer (R) is left to stand in an environment at 25° C. and 50% Rh for 2 hours, a weight change ratio of the resin layer (R) is 0.5% or more.

4. The composite layered body according to claim 3, wherein the resin layer (R) contains a hygroscopic filler.

5. The composite layered body according to claim 3, further comprising a thin film glass that is disposed on the resin layer (R) on a side opposite to the first release layer and that has a thickness of 25 to 100 μm.

6. The composite layered body according to claim 3, further comprising a counter protective layered body that is disposed on the resin layer (R) on a side opposite to the first release layer, wherein:
the counter protective layered body is a layered body including a second substrate layer and a second release layer disposed in contact with one surface or both surfaces of the second substrate layer;
the counter protective layered body is disposed so that a surface thereof on a side of the second release layer is disposed in contact with the resin layer (R); and
the second substrate layer contains a polymer and has a water vapor transmission rate at 40° C. and 90% Rh of smaller than 1 g/m²/day when the second substrate layer is assumed to have a thickness of 100 μm.
